(19) United States
(12) Patent Application Publication
(10) Pub. No.: US 2011/0156123 A1
(43) Pub. Date: Jun. 30, 2011

(54) METHOD FOR MANUFACTURING TWIN BIT STRUCTURE CELL WITH HAFNIUM OXIDE LAYER

(75) Inventor: MIENO FUMITAKE, Shanghai (CN)

(73) Assignee: Semiconductor Manufacturing International (Shanghai) Corporation, Shanghai (CN)

(21) Appl. No.: 12/978,346

(22) Filed: Dec. 23, 2010

(30) Foreign Application Priority Data
Dec. 29, 2009 (CN) 200910247493.8

(51) Int. Cl. H01L 29/772; H01L 21/28

(52) U.S. Cl. 257/315; 438/591; 257/E21.158; 257/E29.242

(57) ABSTRACT

A method for manufacturing a twin bit cell structure of with a hafnium oxide material includes providing a semiconductor substrate having a surface region and forming a gate dielectric layer overlying the surface region. The method forms a polysilicon gate structure overlying the gate dielectric layer and subjects the polysilicon gate structure to an oxidizing environment to cause formation of a first silicon oxide layer overlying the polysilicon gate structure. The method forms an undercut region underneath the polysilicon gate structure and subjects the polysilicon gate structure to an oxidization environment. Thereafter, the method forms a hafnium oxide material overlying the polysilicon gate structure including the undercut region and exposed portions of the gate dielectric layer. The hafnium oxide material is then selectively etched to form an insert region in a portion of the undercut region. A sidewall spacer is formed to isolate and protect the exposed hafnium oxide material.

### CROSS-REFERENCES TO RELATED APPLICATIONS

This application claims priority to Chinese Application No. 200910247493.8; filed on Dec. 29, 2009; which is commonly owned and incorporated by reference herein for all purposes.

### BACKGROUND OF THE INVENTION

Embodiments of the present invention generally relate to integrated circuits and the processing for the manufacture of semiconductor devices. More particularly, embodiments of the invention provide a method and a device for forming a twin bit cell structure for semiconductor integrated circuit devices, but it would be recognized that the invention has a much broader range of applicability. In a specific embodiment, a hafnium oxide material is used to hold charges in a twin-bit structure.

Integrated circuits have evolved from a handful of interconnected devices fabricated on a single chip of silicon to millions of devices. Conventional integrated circuits provide performance and complexity far beyond what was originally imagined. In order to achieve improvements in complexity and circuit density (i.e., the number of devices capable of being packed onto a given chip area), the size of the smallest device feature, also known as the device “geometry”, has become smaller with each generation of integrated circuits.

Increasing circuit density has not only improved the complexity and performance of integrated circuits but has also provided lower cost parts to the consumer. An integrated circuit or chip fabrication facility can cost hundreds of millions, or even billions, of U.S. dollars. Each fabrication facility will have a certain throughput of wafers, and each wafer will have a certain number of integrated circuits on it. Therefore, by making the individual devices of an integrated circuit smaller, more devices may be fabricated on each wafer, thus increasing the output of the fabrication facility. Making devices smaller is very challenging, as each process used in integrated fabrication has a limit. That is to say, a given process typically only works down to a certain feature size, and then either the process or the device layout needs to be changed. An example of such limitation lies in manufacture of memory devices. As feature size continues to shrink, a twin bit cell structure becomes difficult to apply as it is difficult to control the gates independently.

One of the challenges in semiconductor has been the processing of manufacturing twin-bit cell structures for non-volatile memory devices, such as widely used flash based non-volatile memory devices. Among other things, the conventional system and method for manufacturing cells with twin-bit structures face limitations when further scaling down of the cell size is required.

From the above, it is seen that improved techniques for manufacturing and improved materials for twin bit cell structures are desired.

### BRIEF SUMMARY OF THE INVENTION

Embodiments of the present invention provide improved techniques for manufacturing memory devices. More particularly, embodiments of the present invention provide a method and a design for manufacturing a twin bit cell structure for a non-volatile memory device. But it should be recognized that the present invention has a much broader range of applicability.

A specific embodiment of the present invention provides a method for forming a non-volatile memory structure. The method includes providing a semiconductor substrate including a surface region and forming a gate dielectric layer overlying the surface region. The method further includes forming a polysilicon gate structure overlying the gate dielectric layer. In a specific embodiment, the method exposes the gate polysilicon structure to an oxidizing environment to cause formation of a first silicon oxide layer overlying the gate polysilicon structure. Preferably, an undercut region is allowed to be formed underneath the gate polysilicon structure. The method also includes forming a hafnium oxide material overlying the polysilicon gate structure including the undercut region and the gate dielectric layer. In an embodiment, the hafnium oxide material is subjected to a selective etching process to form an insert region in a portion of the undercut region while the insert region remains filled with the hafnium oxide material.

Another embodiment of the present invention provides a non-volatile memory device that includes a semiconductor substrate having a surface region, a gate dielectric layer overlying the surface region, and a polysilicon gate structure overlying the gate dielectric layer. The non-volatile memory device also includes a first undercut region underneath the polysilicon gate structure in a portion of the gate dielectric layer and a first silicon oxide layer covering an underside of the polysilicon gate structure facing the undercut region. Moreover, the non-volatile memory device also includes a hafnium oxide material in an insert region in a portion of the undercut region and a sidewall structure overlying a side region of the polysilicon gate structure and a side region of the hafnium oxide material.

Embodiments of the present invention can provide many benefits over conventional techniques. For example, embodiments of the present invention provide a method to form a reliable twin bit cell structure. In a specific embodiment, a gate structure is formed on top of a dielectric layer, which is later selectively etched to form undercut regions. The undercut regions are used to accommodate a conductive material. For example, the conductive material is used to hold charges for storing information data (i.e., bits). In an embodiment, the conductive material comprises a hafnium oxide material. It is to be appreciated that because embodiments of the present invention provide undercut regions, various etching processes are self-aligned. Embodiments of the present invention provide techniques for forming twin-bit cell structures and allow further scaling down of memory devices in comparison with convention techniques. Various processes and techniques according to embodiments of the present invention can use conventional systems and equipments without major modifications, so that cost effective implementation can be achieved. There are other benefits as well.

Various additional embodiments, features and advantages of the present invention can be more fully appreciated with reference to the detailed description and accompanying drawings that follow.

### BRIEF DESCRIPTION OF THE DRAWINGS

The accompanying drawings, which are incorporated herein and form a part of the specification, illustrate the present invention and, together with the description, further serve to explain embodiments of the invention.

FIG. 1 is a simplified cross-sectional view illustrating a conventional structure of a non-volatile memory device.

FIG. 2 is a simplified flow diagram illustrating a method of forming a gate structure for a non-volatile memory device according to an embodiment of the present invention.

FIG. 3-11 are simplified diagrams illustrating a method of forming a gate structure for a non-volatile memory device according to an embodiment of the present invention.

FIG. 12 is a simplified cross-sectional diagram illustrating a twin bit cell flash memory device according to an embodiment of the present invention.

FIG. 13 is a simplified plot illustrating performance of the non-volatile memory device according to an embodiment of the present invention.

### DETAILED DESCRIPTION OF THE INVENTION

Embodiments of the present invention provide techniques for manufacturing non-volatile memory devices. Merely by way of example, embodiments of the present invention provide a method and a design for manufacturing a twin bit cell structure for a non-volatile memory device. But embodiments according to the present invention can be applied to manufacturing of other semiconductor devices.

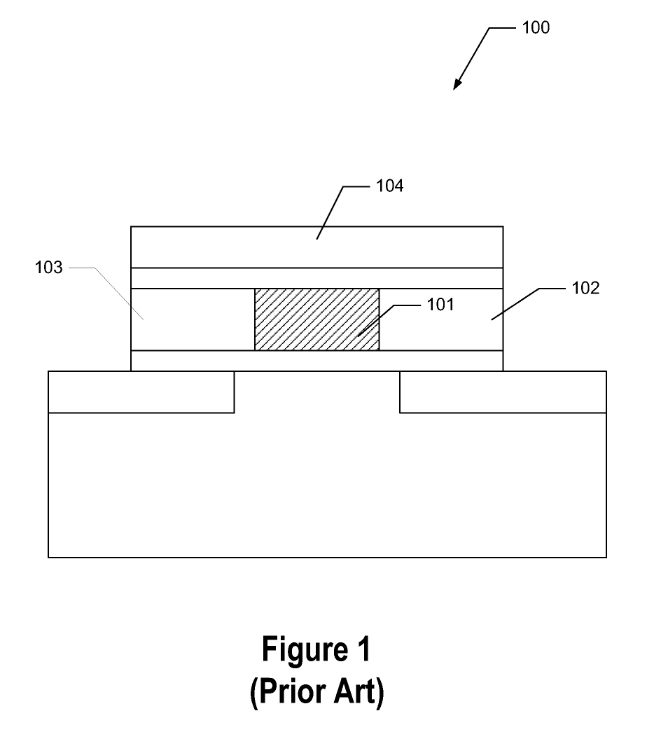

FIG. 1 is a simplified twin bit cell structure using a conventional method of fabrication. As shown in FIG. 1, the twin-bit structure 100 has two conductive regions 102 and 103 that can hold charges. The two conductive regions are separated by an isolation region 101. A control gate 104 overlays the conductive regions.

As an example, the twin bit cell structure shown in FIG. 1 is manufactured using the following steps:
1. provide a p-type substrate;
2. form a gate oxide layer overlaying the substrate;
3. form an n-type doped polysilicon layer;
4. form an HTO (high temperature oxide) layer;
5. form an undoped polysilicon layer;
6. form an HTO layer; and
7. form a layer of n-type doped polysilicon.

Among other things, the conventional manufacturing processes, such as the one outlined above, are difficult to achieve small scale. For example, the formation of an insulating region between the conducting layers (e.g., as provided by the n-type doped regions) is performed by an etching process that can only be scaled down so much. In addition, the use of multiple HTO processes imposes a limitation on the total available thermal budget.

Therefore, it is to be appreciated that innovative manufacturing processes and structures as provided by embodiments of the present invention can further scale down the size of a twin-bit cell structure as compared with conventional techniques. An exemplary process is described in detail below.

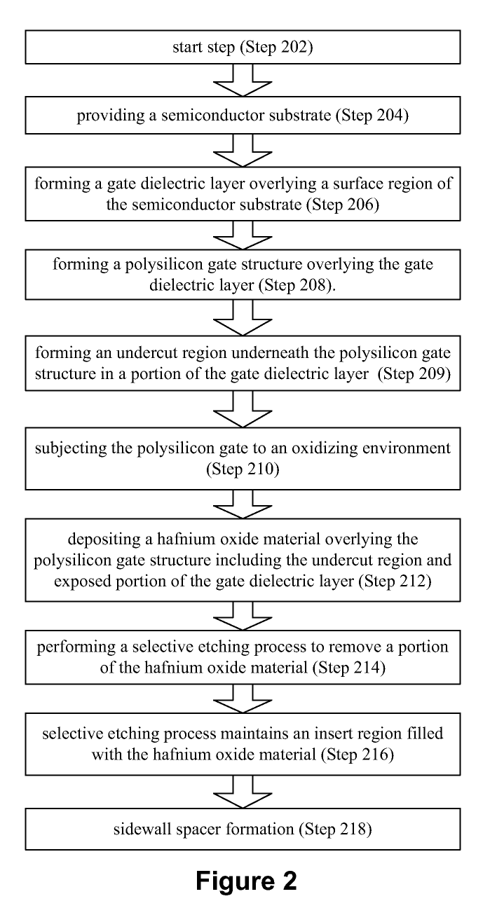

FIG. 2 is a simplified flow diagram illustrating a method of forming a twin-bit cell structure according to an embodiment of the present invention. This diagram is merely an example and should not unduly limit the claims herein. One skilled in the art would recognized other variations, modifications, and alternatives. As an example, various steps described in FIG. 2 can be added, removed, modified, replaced, repeated, rearranged, and/or overlapped.

As shown, the method begins at Step 202. The method includes providing a semiconductor substrate (Step 204). In a specific embodiment, the semiconductor substrate can be a single crystal silicon wafer doped with a P-type impurity. Alternatively, the semiconductor substrate can be a silicon on insulator substrate, commonly known as SOI. In other embodiments, the semiconductor substrate can also be a silicon germanium wafer or others.

The method includes forming a gate dielectric layer overlying a surface region of the semiconductor substrate (Step 206). Depending on the application, the gate dielectric layer can be formed in various ways, such as a silicon oxide that is deposited using a suitable technique, for example, using a thermal growth process. In a specific embodiment, a high temperature oxidation process is used to form a silicon oxide layer of less than 250 angstroms in thickness, which is used as the gate dielectric layer.

The method further includes forming a polysilicon gate structure overlying the gate dielectric layer (Step 208). As an example, the polysilicon gate structure is formed using a deposition process of a doped polysilicon material followed by a patterning and etching process. In a specific embodiment, an LPCVD process is used to form the polysilicon gate layer having a thickness less than 1000 angstroms. For example, silane may be used to perform the LPCVD process as a reactant gas.

In Step 209, an undercut region is formed underneath the polysilicon gate structure in a portion of the gate dielectric layer. In a specific embodiment, this step can be carried out by subjecting the device structure to an isotropic dielectric etching process. As an example, a wet HF etching process can be used. In another example, an isotropic dry dielectric etching process can be used.

As shown in FIG. 2, the method includes subjecting the polysilicon gate to an oxidizing environment (Step 210). In a specific embodiment, the oxidizing environment causes a silicon oxide layer to form overlying a peripheral surface of the polysilicon gate structure including the underside facing the undercut regions in the gate dielectric layer. The oxidizing environment also causes a second oxide layer to form overlying a surface region of the semiconductor substrate facing the undercut regions.

The method then deposits a hafnium oxide material overlying the polysilicon gate structure including the undercut region and exposed portion of the gate dielectric layer (Step 212). According to an embodiment, the hafnium oxide material is deposited using atomic layering depositing process, the hafnium oxide material having a hafnium-to-oxygen ratio of between 1:1.7 to 1:2.3.

The method performs a selective etching process (Step 214) to remove a portion of the hafnium oxide material. In a preferred embodiment, the selective etching process maintains an insert region on each side of the gate dielectric layer, wherein the insert region is filled with the hafnium oxide material (Step 216). In an example embodiment, the gate dielectric layer determines the thickness of the hafnium oxide material.

The method performs other processes to complete the cell structure. In an exemplary embodiment, these other processes can include sidewall spacer formation (Step 218), among others. The method also includes performing other steps to complete the memory device. Of course there can be other modifications, variations, and alternatives.

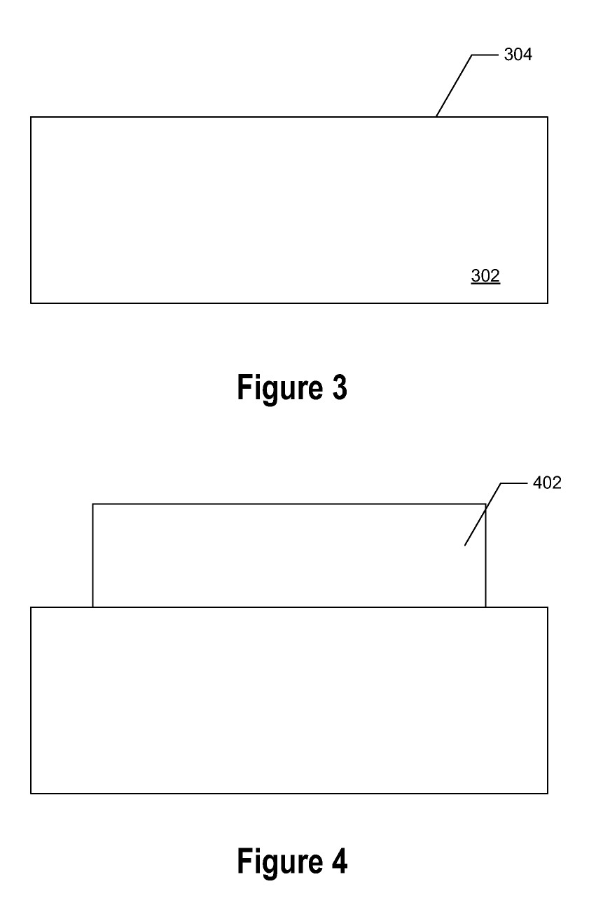

FIGS. 3-11 are simplified cross-sectional view diagrams illustrating a method for forming a twin bit cell structure for a memory device according to an embodiment of the present invention. These diagrams are merely examples and should not unduly limit the claims herein. One skilled in the art would recognized other variations, modifications, and alternatives. It is to be appreciated various steps as illustrated in these figures can be performed in various sequences, repeated, modified, rearranged, and/or overlapped.

As shown in FIG. 3, the method provides a semiconductor substrate 302. The semiconductor substrate can be a single crystal silicon substrate doped with a P-type impurity in a specific embodiment. Alternatively, the semiconductor substrate can be a silicon on insulator substrate, commonly known as SOI. The semiconductor substrate can also be a silicon germanium wafer or others, depending on the embodiment. As shown, the semiconductor substrate includes a surface region 304.

In a specific embodiment, the method includes forming a gate dielectric layer 402 overlying the surface region of the semiconductor substrate as shown in FIG. 4. The gate dielectric layer can be a high density silicon oxide layer formed by a thermal growth process. The gate dielectric layer can also be a composite dielectric stack, for example, silicon oxide on silicon nitride on silicon oxide stack, commonly known as ONO. Other dielectric materials such as silicon nitride, silicon oxynitride, may also be used, depending on the embodiment. Taking a thermally grown oxide as the gate dielectric layer as an example, the gate dielectric can have a thickness ranging from about 20 Angstroms to about 1000 Angstroms. In a specific embodiment, a high temperature oxidation process is used to form the gate dielectric layer 402 comprising silicon oxide, the dielectric layer 402 can have a thickness ranging from about 50 angstroms to about 1000 angstroms. Of course there can be other variations, modifications, and alternatives.

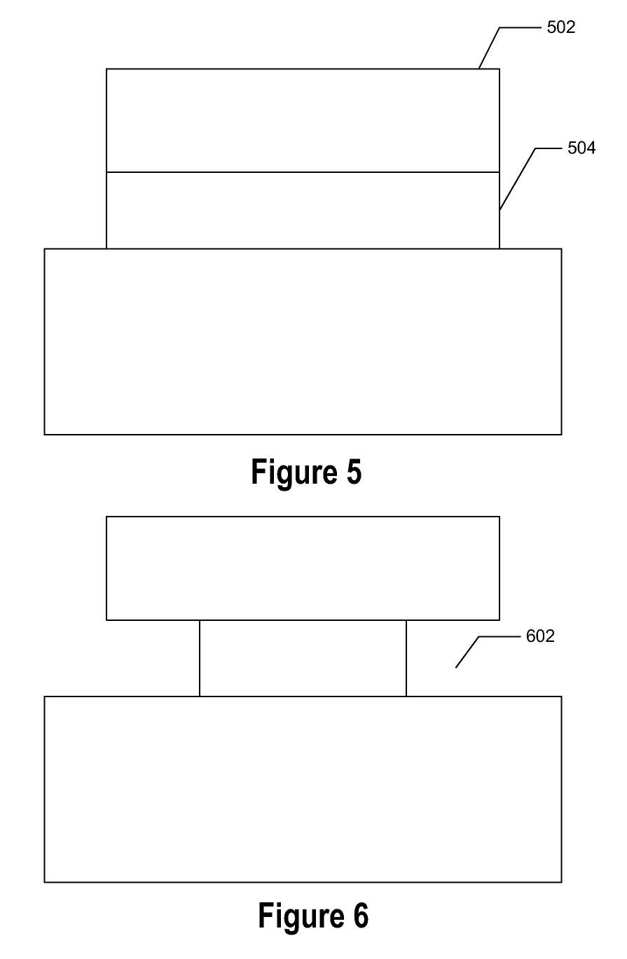

Referring to FIG. 5, the method includes forming a gate structure 502 overlying the gate dielectric layer 504. In a specific embodiment, the gate structure can be a polysilicon gate structure. The polysilicon gate structure can be formed by depositing a polysilicon material followed by a patterning and etching process. For example, an LPCVD process may be used to form the polysillicon gate structure. The polysilicon material may be doped with suitable impurities to provide for a desirable property. In a specific embodiment, the polysilicon material is doped with N-type impurities such as arsenic, phosphorus, or antimony, but can be others. In an example embodiment, the doping concentration of the N-type impurities is approximately between 1.0E18 and 1.0E22 atoms/cm³. Depending on the specific applications, the gate structure 502 may have a thickness ranging from about 300 angstroms to about 5,000 angstroms.

In a specific embodiment, the method forms a first undercut region 602 in a portion of the gate dielectric layer as shown in FIG. 6. The undercut region can be formed using a self-limiting etching process in a specific embodiment. In an example embodiment, the size of the undercut region depends at least on the thickness of the gate dielectric layer. In a specific embodiment, a selective etching process is performed to partially remove the gate dielectric layer, which comprises a silicon oxide material. In an exemplary embodiment, the selectivity of the etching process is afforded by the layers that are surrounding the gate dielectric layer that is to be etched away (e.g., the polysilicon gate structure and the semiconductor substrate together provide alignment for the etching). The undercut region is a void region that is defined by the gate dielectric thickness in a specific embodiment. It is to be appreciated that using the self-limiting etching process as described above, there is no need to use photoresist. Thus, the self-limiting etching process can further scale down the size of a memory device comparing with conventional processes.

Referring to FIG. 6, the etching process can be a wet dielectric etch process, e.g., an HF solution for etching silicon oxide. Alternatively, an isotropic dry etch process suitable for etching the gate dielectric layer can be used. In a specific embodiment, the thin gate dielectric limits the transport of etchant chemicals and etch residues, thereby causing the etch process to be substantially self-limiting. In an embodiment, this is a self-aligned etch process, no lithographic process or photoresist is needed. As a result, the device dimension is not subject to the limitations of the lithographic patterning process. In an example embodiment, the width of the remaining gate dielectric can be smaller than the minimum geometry allowed in the lithographic process. Furthermore, the width of the undercut region can also be made to be smaller than the minimum geometry. As a specific example, the width of the gate dielectric can be that allowed by the minimum geometry, and the undercut regions and the remaining gate dielectric can all be smaller than the minimum geometry. Therefore, a minimum geometry twin-bit memory cell can be formed using this method, enabling a high density memory device.

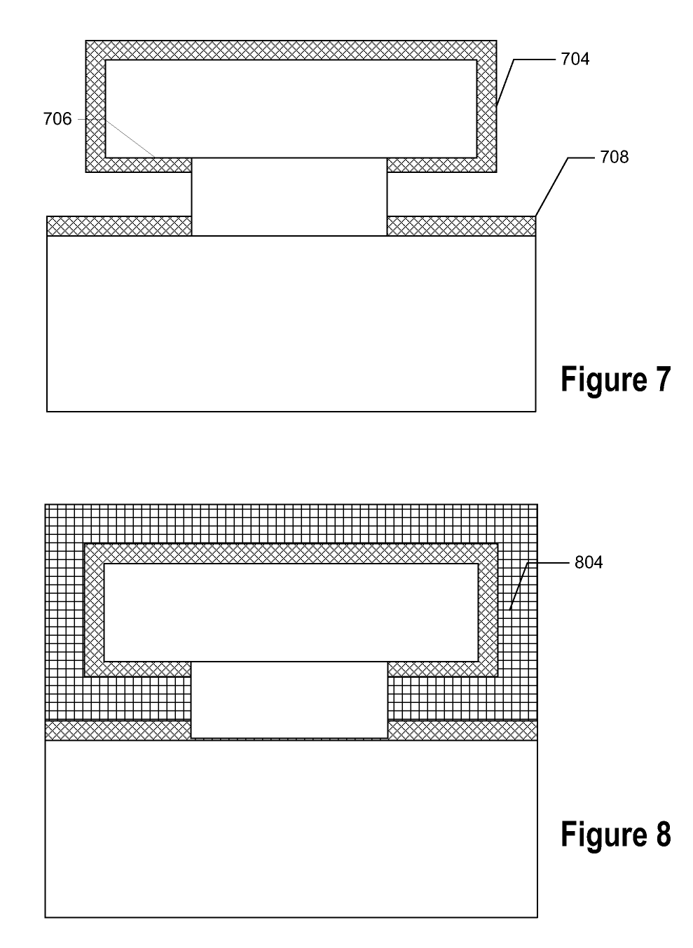

In a specific embodiment, the method includes subjecting the polysilicon gate structure to an oxidizing environment to form an oxide layer as illustrated in FIG. 7. The oxidizing environment causes a first silicon oxide layer 704 to form overlying a portion of the polysilicon gate. For example, the first silicon oxide layer 704 includes an oxide formed polysilicon material that is doped with N-type impurities. The oxidizing environment also causes a second silicon oxide layer 708 to form overlying a surface region of the semiconductor substrate. As shown, a thin silicon oxide layer 708 is formed overlying the surface region of the semiconductor substrate. In an example embodiment, the silicon oxide layer 708 comprises an oxide formed with the doped (P-type) single silicon material. In an embodiment, the first silicon oxide layer has a thickness of about 20 angstroms to 300 angstroms, and the second silicon oxide layer has a thickness of about 20 angstroms to 300 angstroms. Due to the thickness of the first and second silicon oxide layers, the height of the undercut region underneath the polysilicon gate structure is reduced accordingly. In an embodiment, the new undercut region has a height ranging from about 30 angstroms to about 600 angstroms. Of course there can be other variations, modifications, and alternatives.

In a specific embodiment, the method forms a hafnium oxide material 804 overlying a peripheral region of the polysilicon gate structure and the thin oxide layer. The method also fills the second undercut region as shown in FIG. 8. In a specific embodiment, the hafnium oxide material 804 is deposited using an atomic layer depositing technique. In an example embodiment, hafnium oxide material 804 is characterized by a hafnium-to-oxide (Hf:O) ratio of about 1:1.7 to 1:2.3. Depending on the applications, various types of deposition techniques may be used. As shown, the hafnium oxide material 804 fills the undercut region between the gate and the substrate. As shown in FIG. 8, the embodiment of the present invention provides that the thickness of the hafnium oxide material is controlled by the thickness of the gate oxide material. In a specific embodiment, the hafnium oxide material has charge trapping capability to receive and store charges injected into the hafnium oxide material. Of course there can be other variations, modifications, and alternatives.

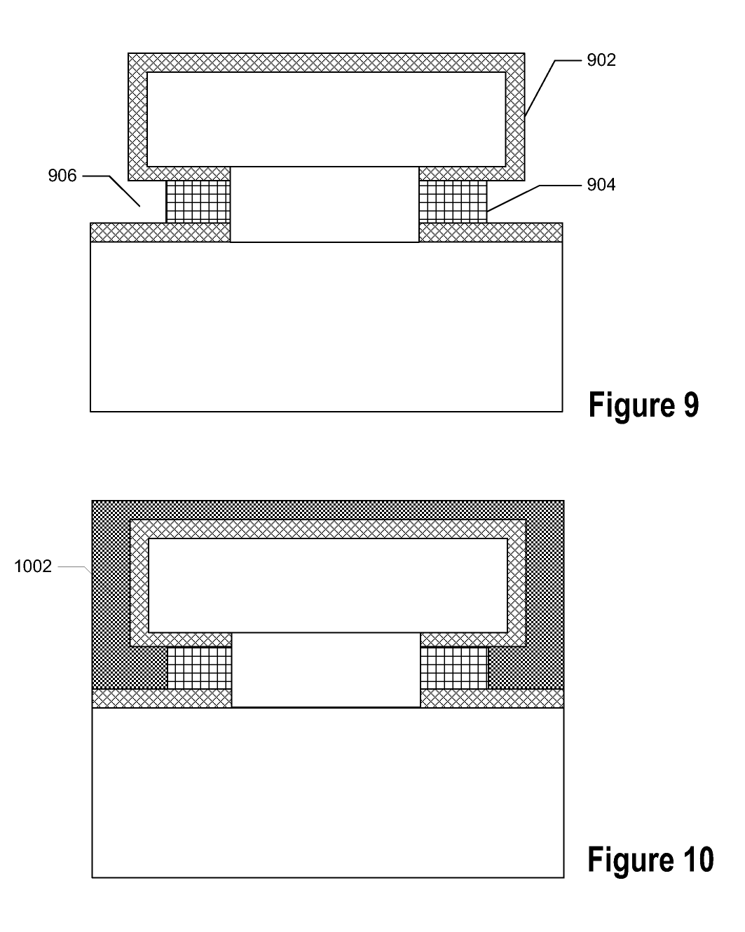

FIG. 9 is a simplified cross-sectional diagram exemplified an embodiment of the present invention. As shown, the method performs a selective etching process to remove a first portion of the hafnium oxide material from the gate structure while maintaining the hafnium oxide material in an insert region 904 within the undercut region. In a specific embodiment, a reactive ion etching (RIE) process is used to remove a portion of the hafnium oxide material. In an exemplary embodiment, a void region 906 is formed after portions of the hafnium oxide material are removed with the RIE process. In an embodiment, the device is placed in a vacuum chamber for the etching process. As shown in FIG. 9, structure 902 can be used to provide the necessary alignment for the selective etching process. The hafnium oxide material in the insert region provides a double side structure with a twin bit function for the memory device in a specific embodiment. In an embodiment, the hafnium oxide material on each side can be adapted to hold charges, so that each side can store a memory bit. The hafnium oxide material on each side is separated by an insulating layer to prevent one charge from interfering with the other. Of course there can be other variations, modifications, and alternatives.

Referring to FIG. 10, the method includes forming a conformal dielectric layer 1002 overlying the polysilicon gate structure and exposed portions of the insert regions. The conformal dielectric layer may be a silicon oxide deposited using TEOS as a precursor in a specific embodiment. The conformal dielectric layer may also be a composite stack such as a silicon oxide on silicon nitride on silicon oxide (or commonly known as SONOS) depending on the embodiment.

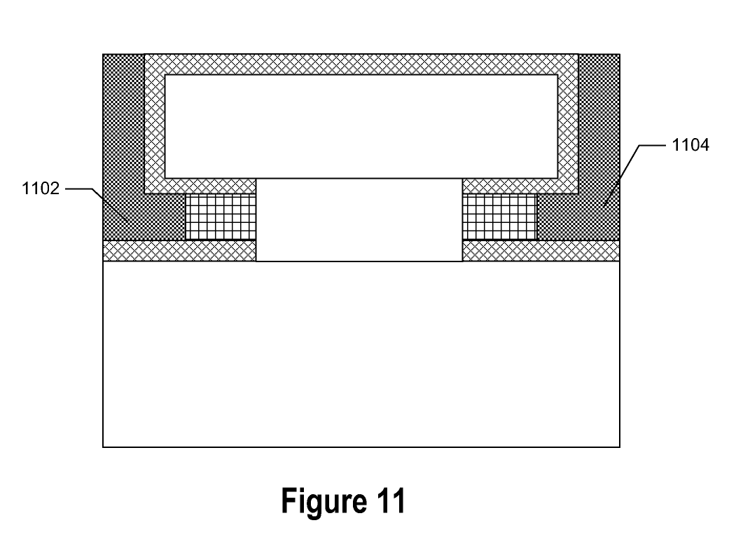

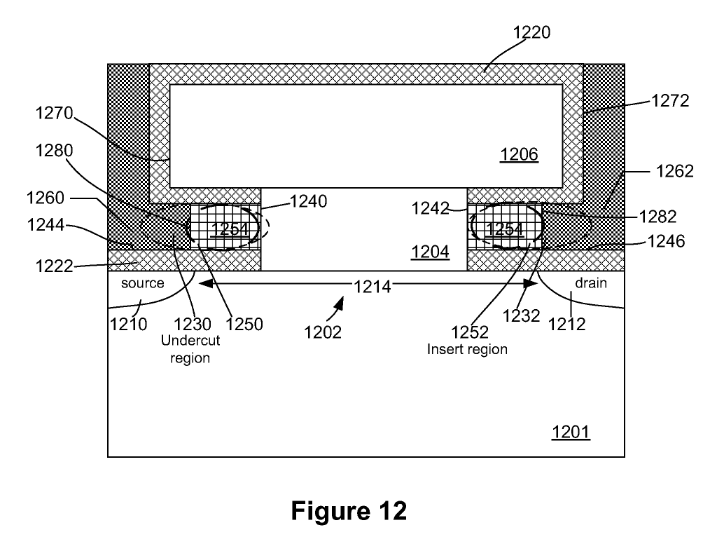

Referring to FIG. 11, the method includes performing a selective etching process to remove the a portion of the dielectric layer 1002, thus forming sidewall spacer structures 1102, 1104 exposing the top portion of the polysilicon gate structure. The sidewall spacer structures 1102 is used to insulate the sides of the polysilicon gate structure and exposed portions of hafnium oxide material in the insert regions. The sidewall spacer structure isolates and protect the polysilicon gate structure in a specific embodiment.

It is to be appreciated that various steps and structures associated with the processed described above can be modified, added, removed, repeated, replaced, and/or overlapped. In a specific embodiment, an implantation process is performed to introduce As into an active region of the device. For example, As can be used to function as N-type dopant.

FIG. 12 is a cross-sectional diagram of a twin-bit cell flash memory device 1200 according to an embodiment of the present invention. The twin-bit cell flash memory device includes a semiconductor substrate 1201 having an active region 1202, a gate dielectric layer 1204 overlying the active region, a polysilicon gate structure 1206 overlying the gate dielectric layer. The semiconductor substrate also contains a source 1210, a drain 1212 and a channel 1214 between the source and the drain. In an embodiment, the active region is formed by an implantation process using an N-type impurity species such as arsenic (As). The twin-bit cell flash memory device also includes a first silicon oxide layer 1220 overlying a peripheral surface of the polysilicon gate structure and a second silicon layer 1222 overlying a surface of the semiconductor substrate. The twin-bit cell flash memory device further includes undercut regions 1230, 1232; each of the undercut regions is surrounded by the first silicon oxide layer covering an underside of the first polysilicon gate structure, a side portion (1240, 1242) of the gate dielectric layer and a surface region (1244, 1246) of the second silicon oxide layer. Each of the undercut regions (1230, 1232) contains an insert region (1250, 1252) filled with an aluminum oxide material 1254. Additionally, the twin-bit cell flash memory device includes sidewall spacer structures 1260, 1262; each of the sidewall spacer structures overlies an exposed vertical side region (1270, 1272) of the first silicon oxide layer, an exposed vertical side (1280, 1282) of the hafnium oxide material, and a portion of the surface regions (1244, 1246) of the second silicon oxide layer. In an embodiment, each insert region containing the hafnium oxide material functions as a charge trapping region to receive and hold electrons injected into the hafnium oxide material to form a twin bit cell structure; and the sidewall spacer structures are used to insulate the sides of the polysilicon gate structure and the exposed portions of the hafnium oxide material in the insert regions. According to an embodiment, the hafnium oxide material is deposited using atomic layering depositing process, the aluminum oxide material having a hafnium-to-oxygen ratio of between 1:1.7 to 1:2.3.

In an embodiment of the non-volatile memory device, the first silicon oxide layer includes oxidized polysilicon material. In another embodiment, the first silicon oxide layer is formed by oxidizing the polysilicon gate structure. In another embodiment, the non-volatile memory device also includes a second silicon oxide layer overlying a surface region of the semiconductor substrate facing the undercut region. In another embodiment, the non-volatile memory device further includes a second undercut region at least partially filled with the hafnium oxide material. In yet another embodiment, the hafnium oxide material is characterized by a dielectric k value of about eight and greater. In another embodiment, the polysilicon gate structure is characterized by a width defined by the minimum geometry of a patterning process.

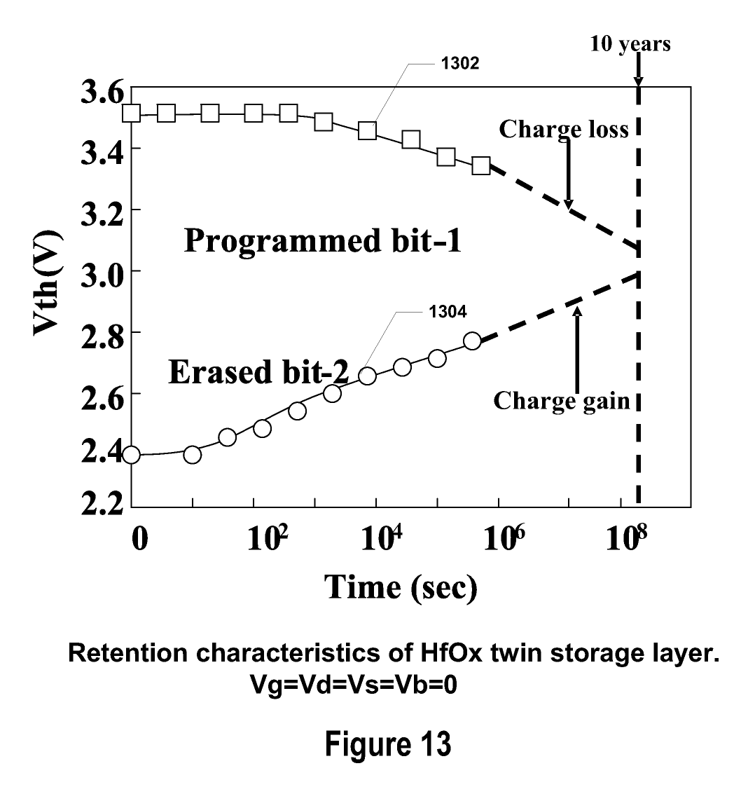

FIG. 13 is a simplified plot illustrating a retention characteristics of the twin bit memory device using hafnium oxide material according to an embodiment of the present invention. This plot is merely an example and should not unduly limit the claims herein. One skilled in the art would recognize other variations, modifications, and alternatives. As shown, a plot of threshold voltage (Vth) as a function of time is provided. The threshold voltage of a programmed bit 1302 is maintained at about 3.4 volt with no charge loss over a time period of 10⁸ seconds. The threshold voltage of an erased bit 1304 is also maintained at a value of about 2.5 volts with no charge loss over the time period. The respective threshold voltages are measured at Vg=Vd=Vs=Vb=0. Of course there can be other modifications, variations, and alternatives.

Although specific embodiments of the present invention have been described, it will be understood by those of skill in the art that there are other embodiments that are equivalent to the described embodiments. Accordingly, it is to be understood that the invention is not to be limited by the specific illustrated embodiments, but only by the scope of the appended claims.

What is claimed is:

1. A method for forming a non-volatile memory structure, the method comprising:
providing a semiconductor substrate including a surface region;
forming a gate dielectric layer overlying the surface region;
forming a polysilicon gate structure overlying the gate dielectric layer;
forming a first undercut region and a second undercut region underneath the polysilicon gate structure in a portion of the gate dielectric layer;
subjecting the polysilicon gate structure to an oxidizing environment to cause the formation of a first silicon oxide layer overlying a peripheral surface of the polysilicon gate structure;
depositing a hafnium oxide material overlying the polysilicon gate structure including the first and second undercut regions;
selectively etching a first portion and a second portion of the hafnium oxide material while maintaining the hafnium oxide material in an associated first insert region and an associated second insert region in the respective first and second undercut regions; and
forming a sidewall structure overlying a side region of the polysilicon gate structure.

2. The method of claim 1, wherein the polysilicon gate structure is doped with an N-type dopant having a doping concentration ranging from about 1.0E18 to about 1.0E22 atoms/cm³.

3. The method of claim 1, wherein the sidewall spacer structure is formed by depositing a conformal dielectric layer overlying the polysilicon gate structure followed by a selective etching process.

4. The method of claim 1 further comprising forming a second silicon oxide layer overlying a surface region of the semiconductor substrate facing the first and second undercut regions.

5. The method of claim 1, wherein the first and second undercut regions are formed using a self-limiting etching process.

6. The method of claim 1, wherein the first and second undercut regions are a void region.

7. The method of claim 1, wherein the hafnium oxide material comprises a dielectric k value of about eight and greater.

8. The method of claim 1, wherein the hafnium oxide material is formed using atomic layer deposition.

9. The method of claim 8, wherein the hafnium oxide material has a hafnium to oxygen (Hf:O) ratio of about 1:1.7 to about 1:2.3.

10. The method of claim 1, wherein the first and second insert regions provide a double-sided bit structure.

11. The method of claim 1, wherein the hafnium oxide material is characterized by a first thickness, the first thickness being controlled by a thickness of the gate dielectric layer.

12. The method of claim 1 further comprises forming active regions in a vicinity of the surface region of the semiconductor substrate.

13. The method of claim 12, wherein the active regions are formed by an implantation process using an N type arsenic as an impurity species and the polysilicon gate structure, including the sidewall spacer as a mask.

14. The method of claim 1, wherein the selective etching process comprises a reactive ion etching process.

15. A non-volatile memory device comprising:
a semiconductor substrate including a surface region;
a gate dielectric layer overlying the surface region;
a polysilicon gate structure overlying the gate dielectric layer;
a first undercut region and a second undercut region underneath the polysilicon gate structure in a portion of each side of the gate dielectric layer;
a first silicon oxide layer covering a peripheral surface of the polysilicon gate structure including the underside facing the undercut region;
a hafnium oxide material in an insert region in a portion of each of the first and second undercut regions; and
a sidewall spacer structure overlying a side region of the polysilicon gate structure and a side region of the hafnium oxide material.

16. The memory device of claim 15, wherein the first silicon oxide layer comprises oxidized polysilicon material.

17. The memory device of claim 15 further comprising a second silicon oxide layer overlying a surface region of the semiconductor substrate facing the undercut region.

18. The memory device of claim 15 further comprising a second undercut region at least partially filled with the hafnium oxide material.

19. The memory device of claim 15, wherein the hafnium oxide material is characterized by a dielectric k value of about eight and greater.

20. The memory device of claim 15, wherein the polysilicon gate structure is characterized by a width defined by the minimum geometry of a patterning process.
